(19) United States
(12) Patent Application Publication
(10) Pub. No.: US 2012/0032279 A1
(43) Pub. Date: Feb. 9, 2012

(54) III-V METAL-OXIDE-SEMICONDUCTOR DEVICE

(75) Inventors: Edward Yi CHANG, Hsinchu County (TW); Yueh-Chin LIN, TAIPEI COUNTY (TW)

(73) Assignee: NATIONAL CHIAO TUNG UNIVERSITY, HSINCHU (TW)

(21) Appl. No.: 12/849,025

(22) Filed: Aug. 3, 2010

(51) Int. Cl. H01L 29/20; H01L 29/94; H01L 29/78

(52) U.S. Cl. 257/410; 257/615; 257/532; 257/296; 257/E29.345; 257/E29.255; 257/E29.089

(57) ABSTRACT

A barrier layer, hafnium oxide layer, between a III-V semiconductor layer and an lanthanum oxide layer is used to prevent interaction between the III-V semiconductor layer and the lanthanum oxide layer. Meanwhile, the high dielectric constant of the lanthanum oxide can be used to increase the capacitance of the semiconductor device.

### BACKGROUND

1. Technical Field

The disclosure relates to a structure of metal-oxide-semiconductor. More particularly, the disclosure relates to a structure of III-V metal-oxide-semiconductor.

2. Description of Related Art

With the continuously decrease of the semiconductor device's size, the unit capacitance of a metal-oxide-semiconductor (MOS) structure needs to be continuously increased. For satisfying the requirement of the high unit capacitance, the dielectric constant of the oxide layer in the MOS structure needs to be high enough to avoid current leakage problem and maintain a sufficient thin thickness. However, to find a suitable oxide layer that has a really high dielectric constant and really low current leakage for III-V semiconductor is a difficult task.

### SUMMARY

Accordingly, an oxide layer that has a high dielectric constant and can be used in the III-V MOS structure is provided.

According to an embodiment, lanthanum oxide which has a really high dielectric constant of about 30 is used to be the oxide layer in the III-V MOS devices. However, the lanthanum oxide was found that it had some interaction with the III-V semiconductor layer to cause large current leakage. Therefore, a hafnium oxide layer was tried to be disposed between the lanthanum oxide layer and the III-V semiconductor layer. It was found that hafnium oxide layer with a thickness not less than 3 nm can successfully separate the lanthanum oxide layer and the III-V semiconductor layer to take the advantages of the high dielectric constant of lanthanum oxide.

Accordingly, the oxide layer composed of hafnium oxide layer and lanthanum oxide layer can effectively increase the capacity of the III-V devices and solve the current leakage problem at the same time.

It is to be understood that both the foregoing general description and the following detailed description are by examples, and are intended to provide further explanation of the invention as claimed.

### BRIEF DESCRIPTION OF THE DRAWINGS

FIG. 1A is a diagram of C-V curves of hafnium oxide-InGaAs MOS capacitor under various operation frequencies.

FIG. 1B is a diagram of I-V curves of hafnium oxide-InGaAs MOS FET applied by various gate voltages.

FIG. 2 is a cross-sectional diagram of the structure of the MOS capacitor.

FIG. 3A is a diagram of C-V curves of 12 nm lanthanum oxide-InGaAs MOS capacitor under various operation frequencies.

FIG. 3B is a diagram of J-V curve of 12 nm lanthanum oxide-InGaAs MOS capacitor.

FIGS. 4A-4C are diagrams of C-V curves of 8 nm lanthanum oxide/1 nm hafnium oxide-In_{0.53}Ga_{0.47}As, 7 nm lanthanum oxide/2 nm hafnium oxide-In_{0.53}Ga_{0.47}As, and 6 nm lanthanum oxide/3 nm hafnium oxide-In_{0.53}Ga_{0.47}As MOS capacitors under various operation frequencies, respectively.

FIG. 5 is a diagram of C-V curves of 9 nm hafnium oxide-InGaAs MOS capacitor under various operation frequencies.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Conventionally, aluminum oxide, hafnium oxide, or a combination of aluminum oxide and hafnium oxide is used as the gate oxide layer of InGaAs metal-oxide-semiconductor (MOS) field effect transistor (FET). For testing the properties of the oxide and the semiconductor of a MOS FET, a MOS capacitor is usually formed and tested first.

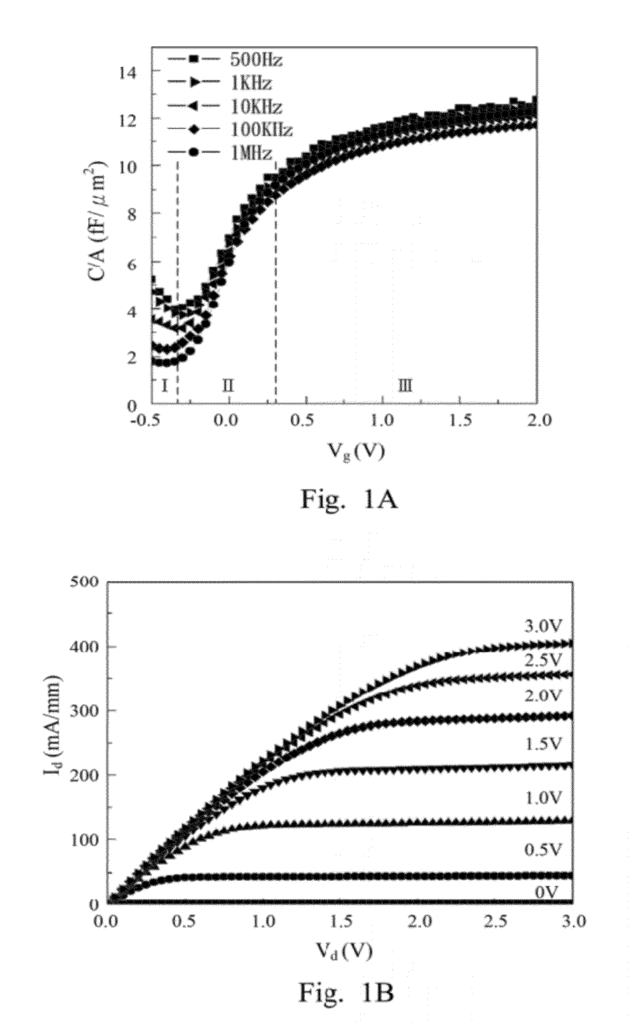

Typical C-V curves of the hafnium oxide-InGaAs MOS capacitor under various operation frequencies are shown in FIG. 1A. In the strong inversion region (region I) of FIG. 1A, if the capacity of the MOS capacitor is higher, more charge carrier will be generated in the MOS FET. In the accumulation region (region III) of FIG. 1A, if the capacity of the MOS capacitor is higher, the oxide layer of the MOS capacitor has a higher dielectric constant. The region between the strong inversion region (region I) and the accumulation region (region III) in FIG. 1A is depletion region (region II).

Later, the MOS FET is formed, and the typical I-V curves of the hafnium oxide-InGaAs MOS FET applied by various gate voltages are shown in FIG. 1B.

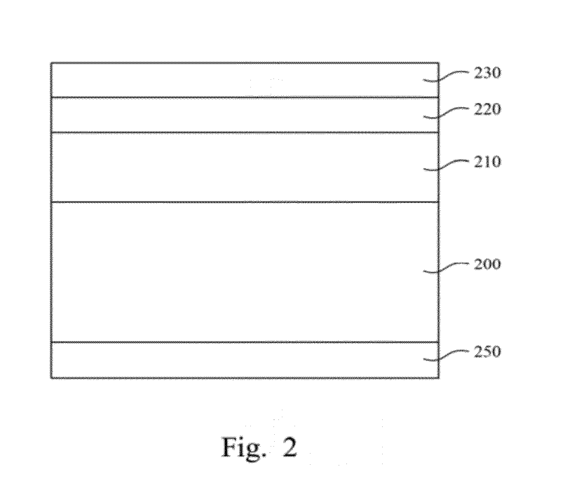

According to the embodiments of this invention, a lanthanum oxide-InGaAs MOS capacitor and lanthanum oxide/hafnium oxide-InGaAs MOS capacitors were formed and tested for finding a better oxide material. The structure of the MOS capacitor is shown in FIG. 2. The MOS capacitor is formed by the following method. A 100 nm n-type In_{0.53}Ga_{0.47}As layer 210 was epitaxially grown on a n-type InP substrate 200, and the Si dopant density in the In_{0.53}Ga_{0.47}As layer 210 was 5×10¹⁷ cm⁻³. The In_{0.53}Ga_{0.47}As layer 210 was then chemically cleaned by acetone, ethanol and dipped in HF solution.

Next, an oxide layer 220 was formed on the In_{0.53}Ga_{0.47}As layer 210 by molecular beam deposition. The oxide layer 220 was lanthanum oxide, hafnium oxide, or a combination of lanthanum oxide and hafnium oxide. Afterwards, the oxide layer 220 was subjected to post deposition annealing (PDA) conducted in forming gas (H₂: 3%, N₂: 97%) at 600° C.

Subsequently, a 50 nm aluminum metal layer 230 was formed on oxide layer 220 by sputtering and etching. Finally, a 50 nm aluminum back contact 250 was formed on the back side of the InP substrate 200. The aluminum metal layer 230 and the aluminum back contact 250 can be formed by sputtering and etching.

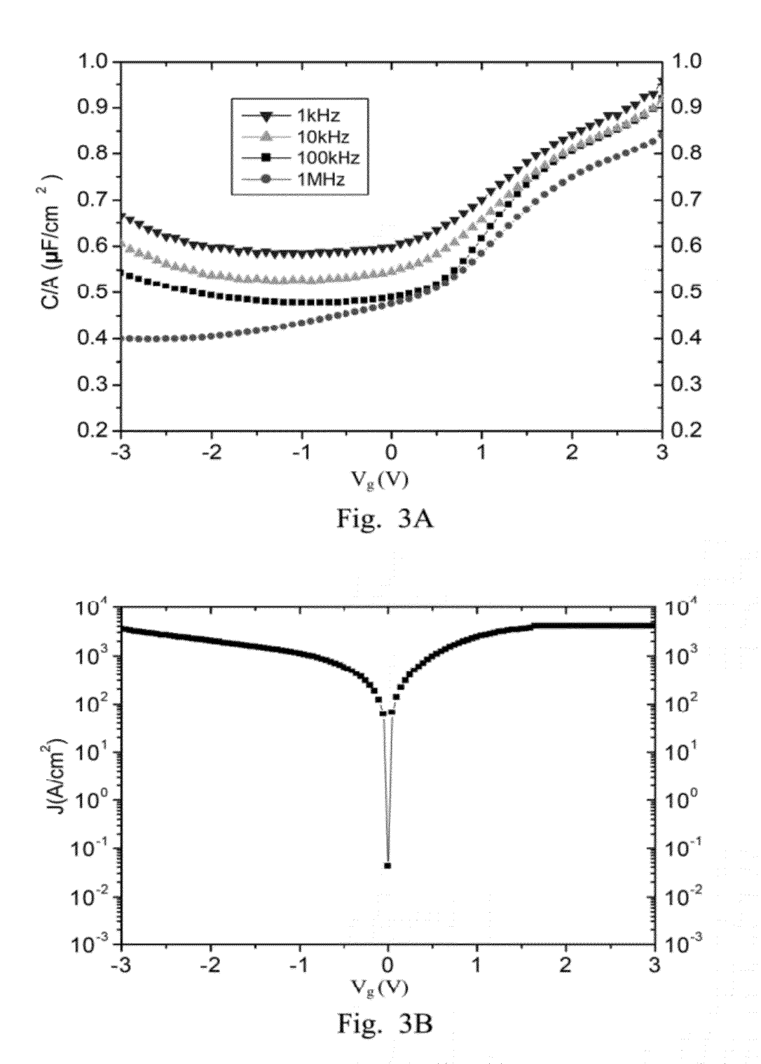

Since the dielectric constant of lanthanum oxide is quite high (about 30), the first embodiment used 12 nm lanthanum oxide layer to be the material of the oxide layer 220 in FIG. 2. However, in FIG. 3A, the C-V curves of the 12 nm lanthanum oxide-In_{0.53}Ga_{0.47}As MOS capacitor were quite dispersed and lack of strong inversion region as in FIG. 1A. Therefore, it showed that the MOS capacitor was eclectically failed. FIG. 3B is a diagram of J-V curve of 12 nm lanthanum oxide-InGaAs MOS capacitor. In FIG. 3B, large gate leakage current (more than 1000 A/cm²) in the investigated range of the applied gate voltage was observed. Accordingly, it seems that some interaction was existed between the lanthanum oxide and In_{0.53}Ga_{0.47}As.

In the photographs of tunneling electron microscopy (TEM) and the results of Energy Dispersive Spectrum (EDS), it was found that In_{0.53}Ga_{0.47}As diffused into the lanthanum oxide layer, and thus the MOS capacitor failed.

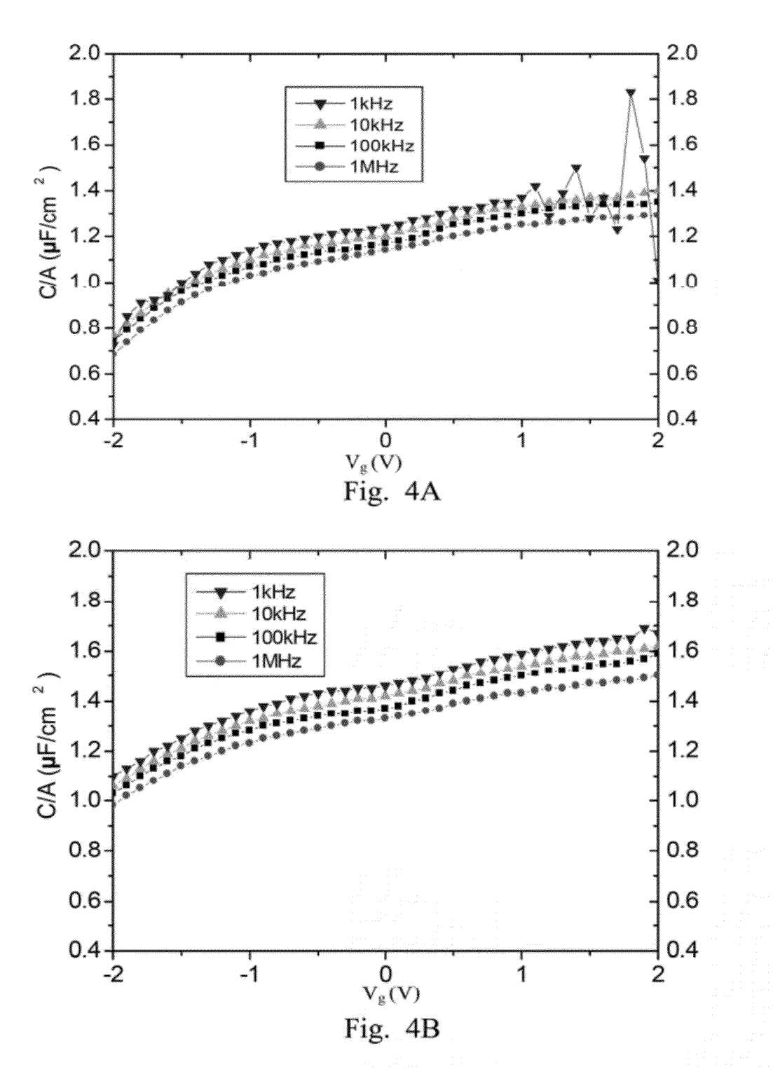

Next, hafnium oxide was used as a barrier layer between lanthanum oxide and In_{0.53}Ga_{0.47}As. Although the dielectric constant of hafnium oxide is smaller (about 25) then the dielectric constant of lanthanum oxide (about 30), but hafnium oxide has a wider band gap (about 5.7 eV) than lanthanum oxide (about 4.3 eV). Therefore, the oxide layer 220 in the MOS capacitor structure in FIG. 2 is a combination of 8 nm lanthanum oxide/1 nm hafnium oxide, 7 nm lanthanum oxide/2 nm hafnium oxide, or 6 nm lanthanum oxide/3 nm hafnium oxide in the following embodiments. The C-V curves of the above MOS capacitors are sequentially shown in FIGS. 4A-4C.

The C-V curves in FIGS. 4A and 4B do not show the strong inversion region. Therefore, it showed that the 1 nm or 2 nm hafnium oxide layer cannot successfully stop the In_{0.53}Ga_{0.47}As substrate diffused into the lanthanum oxide layer. Since a thin film with relatively low resistivity is often formed between III-V semiconductor material and oxide layer, large frequency dispersion in the C-V curves is usually observed. However, in FIG. 4C, the frequency dispersion of the C-V curves is quite small. It showed that the 3 nm hafnium oxide layer can successfully inhibit the formation of the thin film between III-V semiconductor material and oxide layer.

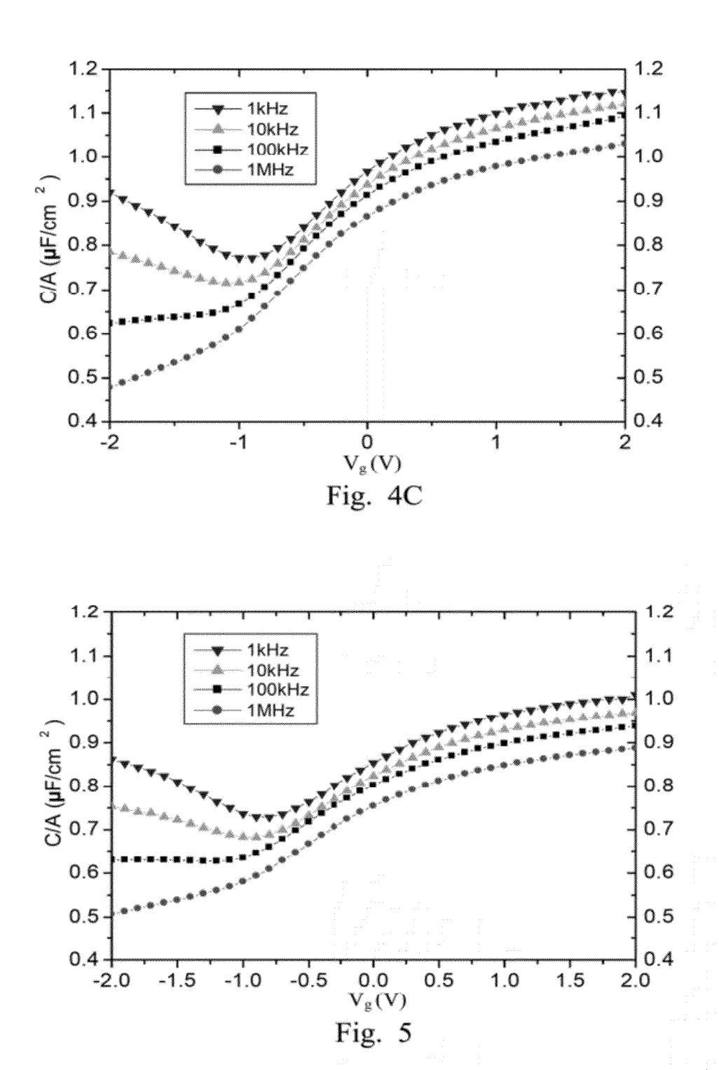

Next, 9 nm hafnium oxide layer was used to be the oxide layer 220 of the MOS capacitor in FIG. 2. The C-V curves were shown in FIG. 5. Comparing the C-V curves in FIG. 4C and FIG. 5, it shows that when the oxide layer is 6 nm lanthanum oxide/3 nm hafnium oxide (FIG. 4C), the MOS capacitor has a larger capacitance and a smaller frequency dispersion. This means that the dielectric constant of the 6 nm lanthanum oxide/3 nm hafnium oxide is greater than the dielectric constant of the 9 nm hafnium oxide layer. Moreover, the calculated equivalent oxide thicknesses (EOTs) of the 6 nm lanthanum oxide/3 nm hafnium oxide and the 9 nm hafnium oxide is about 3.001 and 3.417, respectively. It showed that the 6 nm lanthanum oxide/3 nm hafnium oxide has a smaller EOT, which is consistent with the above result that the 6 nm lanthanum oxide/3 nm hafnium oxide MOS capacitor has a greater capacity.

From the result above, the combination of a first oxide layer having a higher dielectric constant and a second oxide layer having a wider band gap can meet the requirements of increasing the capacity of the III-V devices and solving the current leakage problem at the same time.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A III-V metal-oxide-semiconductor (MOS) device, comprising:
a III-V semiconductor layer on a substrate;
a hafnium oxide layer on the III-V semiconductor layer;
a lanthanum oxide layer on the hafnium oxide layer; and
a metal layer on the lanthanum oxide layer.

2. The III-V MOS device of claim 1, wherein the III-V semiconductor layer is InAs layer.

3. The III-V MOS device of claim 1, wherein the III-V semiconductor layer is InGaAs layer.

4. The III-V MOS device of claim 3, wherein the III-V semiconductor layer is In_{0.53}Ga_{0.47}As layer.

5. The III-V MOS device of claim 1, wherein the thickness of the hafnium oxide layer is not less than 3 nm.

6. The III-V MOS device of claim 1, further comprising a metal back contact on the backside of the substrate.

7. A III-V metal-oxide-semiconductor (MOS) device, comprising:
a barrier layer between a III-V semiconductor layer and an oxide layer for preventing interaction between the III-V semiconductor layer and the oxide layer.

8. The III-V MOS device of claim 7, wherein the barrier layer is hafnium oxide layer.

9. The III-V MOS device of claim 8, wherein the III-V semiconductor layer is InGaAs layer and the oxide layer is lanthanum oxide layer.

10. The III-V MOS device of claim 8, wherein the III-V semiconductor layer is In_{0.53}Ga_{0.47}As layer and the oxide layer is lanthanum oxide layer.
